(19) United States
(12) Patent Application Publication
(10) Pub. No.: US 2003/0024691 A1
(43) Pub. Date: Feb. 6, 2003

(54) High efficiency heat sink

(76) Inventors: Leu-Wen Tsay, Taipei (TW); Ren-Kae Shiue, Hualien Hsien (TW); Yuan-Cheng Liao, Taoyuan (TW)

Correspondence Address: INTELLECTUAL PROPERTY SOLUTIONS, INCORPORATED, 5717 COLFAX AVENUE, ALEXANDRIA, VA, 22311, US

(21) Appl. No.: 09/917,665

(22) Filed: Jul. 31, 2001

(51) Int. Cl. F28D 15/00; H05K 7/20; H01L 23/34

(52) U.S. Cl. 165/104.26; 165/104.33; 361/700; 257/715

(57) ABSTRACT

A high efficiency heat sink includes a first chamber, a second chamber and at least one cooling fin. The first chamber contains coolant and absorbs heat from a heat source, vaporizing the coolant. The second chamber receives the vaporized coolant from the first chamber, transmits the heat from the vaporized coolant to the cooling fin so that the vaporized coolant is condensed, and forces the condensed coolant back to the first chamber via capillary pressure.

### BACKGROUND OF THE INVENTION

1. Field of the Invention

The present invention relates in general to a high efficiency heat sink suited to cooling hot components in computers.

2. Description of the Related Art

Ever-increasing workloads placed on modern-day computers, combined with higher operating speeds, heat generated by components in computers is often increased to extreme levels. The use of a heat sink especially for cooling the central processing unit (CPU), which generates significant heat during operation, is necessary in order to avoid failure of the CPU due to overheating. Heat dissipation of hot components in a portable computer is especially challenging. Generally, in a portable computer, copper heat pipes are used for cooling the CPU or other components. The heat pipes contain coolant (e.g. water) inside. The coolant is vaporized at the hot end of the heat pipe, expands and rapidly flows toward the cool end of the heat pipe, changes into supersaturated vapor or condensed liquid at the cool end of the heat pipe, and then flows back to the hot end of the heat pipe via capillary pressure. The coolant flows between the hot end and cool end of the heat pipe in cycles to dissipate heat from the hot components in the portable computer.

The inner surfaces of the heat pipe are necessarily roughened with a plurality of pores, to enhance the capillary action and improve the convection effect. Generally, the inner surfaces of the heat pipe are roughened by grooving, chemical etching or embossing. Alternatively, fine copper nets or metallic powders are disposed in the heat pipe to provide rough inner surfaces. Furthermore, the heat pipe is pressed flat, which provides a large contact area between the heat pipe and the hot component, thereby enhancing the heat conduction therebetween. The heat pipe is thus required to be as flat as possible. Generally, the heat pipe is produced in the following manner: (I) a cylindrical tube having rough inner surfaces is prepared; (II) one end of the cylindrical tube is seal-welded by arc or gas welding; (III) the cylindrical tube is filled with coolant under vacuum conditions; (IV) the other end of the cylindrical tube is firstly clamped then seal-welded by arc welding or gas welding; (V) the tube is pressed flat mechanically. A heat pipe with a large cross section provides higher heat transfer capacity. However, mechanically pressing this type of heat pipe with large surface area very flat is technically difficult. In other words, it is difficult to mechanically press an originally round copper tube of large diameter into a flat heat pipe with accurate internal gap, which provides the coolant flow. Manufacturers therefore prefer the use of two or more heat pipes to increment of the heat transfer capacity when a single heat pipe cannot provide the necessary heat dissipation. Furthermore, the heat pipes are connected to air-cooling fins via gluing (by polymer glue of good heat conduction) or soldering (by the Zincate process to join aluminum fins and copper heat pipes). The heat pipes transmit heat to the air-cooling fins via heat conduction. The air-cooling fins then transmit the heat to the atmosphere via primarily heat convection. The efficiency of heat dissipation from this process is poor since the contact area between the heat pipes and the air-cooling fins is very limited compared with the present invention.

### SUMMARY OF THE INVENTION

An object of the present invention is to provide an improved heat sink capable of efficiently dissipating heat from a hot component, even if the component is working at a high temperature or has a large area.

The heat sink of the present invention includes a bottom plate, a top plate, a division plate and at least one cooling fin. The bottom plate contacts the heat source. The cooling fin is connected to the top plate. The division plate is disposed between the bottom plate and the top plate to create a first chamber between the bottom plate and the division plate and create a second chamber between the top plate and the division plate. A guiding layer is filled in the first chamber in order to enhance capillary flow of the condensed coolant. Coolant then flows between the first chamber and the second chamber to transmit the heat from the heat source to the fin.

The heat transfer capacity of the heat sink of the present invention is mainly determined by the surface area of the plates. Enlargement of the plates to increase the heat transfer capacity of the heat sink is technically very easy, and heat transfer capacity of the present invention is considerably improved than that of current heat pipe.

### BRIEF DESCRIPTION OF THE DRAWINGS

The present invention can be more fully understood by reading the subsequent detailed description and examples with references made to the accompanying drawings, wherein:

FIG. 1A is a perspective diagram of a heat sink in accordance with the present invention;

FIG. 1B is an exploded diagram of the heat sink of FIG. 1A;

FIG. 2 is a plan view of the components of the heat sink of FIG. 1B;

FIG. 3A is a perspective diagram of the division plate of the heat sink in accordance with the present invention;

FIG. 3B is a local enlarged view of the division plate of the heat sink in accordance with the present invention;

FIG. 4A is a plane view of the heat sink in accordance with the present invention;

FIG. 4B is a sectional view of the heat sink along line IVB-IVB of FIG. 4A; and

FIG. 4C is a sectional view of the heat sink along line IVC-IVC of FIG. 4A.

### DETAILED DESCRIPTION OF THE PREFERRED EMBODIMENT

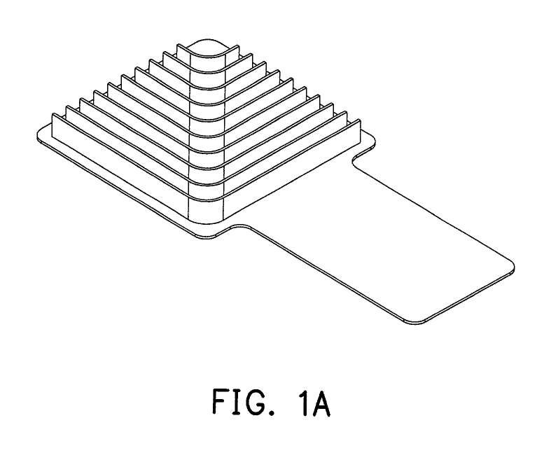

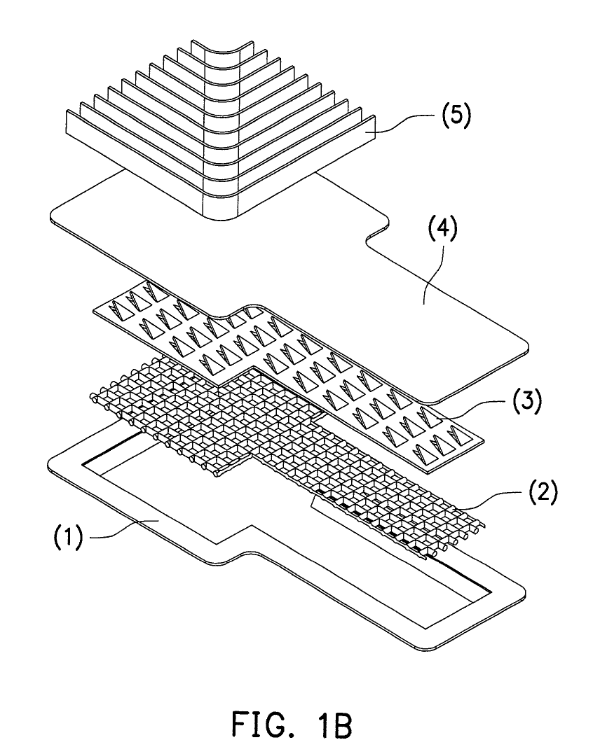

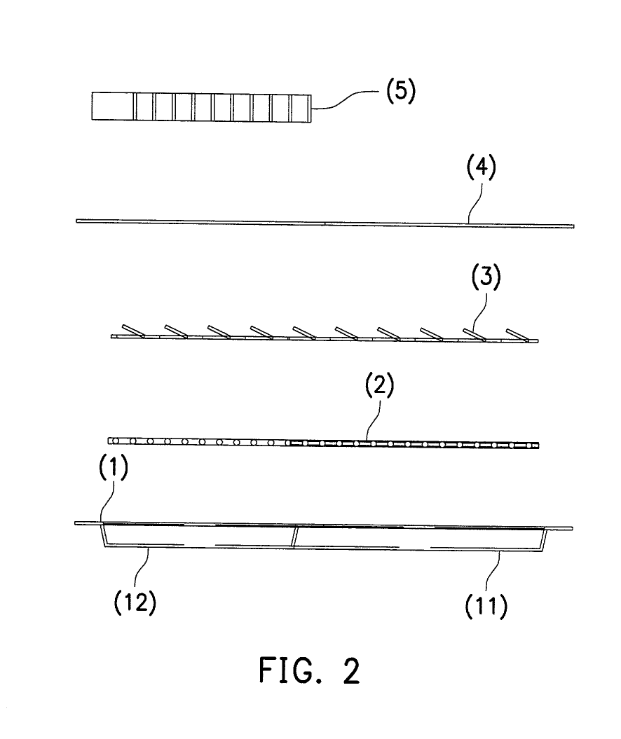

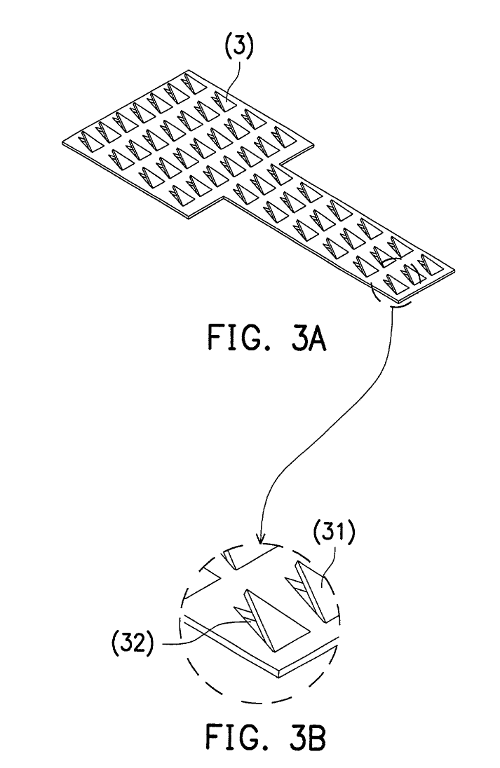

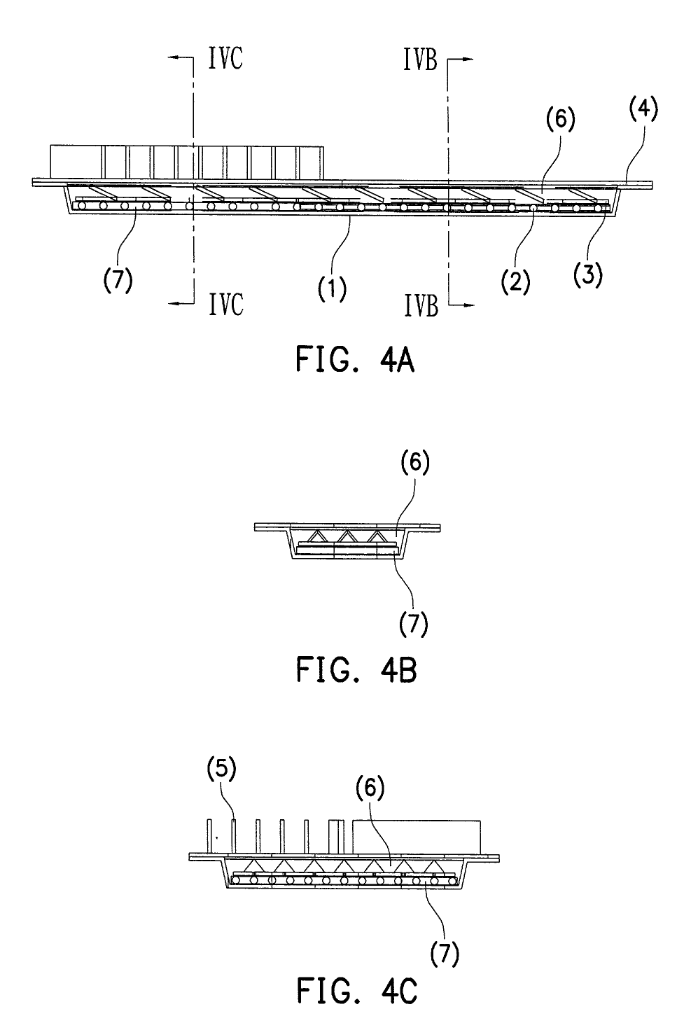

Referring to FIGS. 1A and 1B, a heat sink of the present invention includes a bottom plate (1), a guiding layer (2), a perforated division plate (3), a top plate (4) and a plurality of air-cooling fins (5). Referring to FIG. 2, the bottom plate (1) has a flat bottom surface at its heated side (11), contacting a hot component (not shown in the Figure) in order to draw off excess heat. The coolant in the heat sink is heated and then vaporized in the heated side (11). FIG. 3A shows a perspective diagram of the division plate (3) of the heat sink in accordance with the present invention. The division plate contains a plurality of protrusions (31) as shown in FIG. 3B. The top of protrusions (31) are in contact with the top plate (4) in order to form the second chamber (6) as shown in FIGS. 4A, 4B and 4C. Also referring to FIG. 3B, the vapor flows through the vents (32) of the perforated division plate (3) to the second chamber (6) defined between the top plate (4) and the division plate (3). Then, the vapor is cooled by the air-cooling fins (5) and changes into supersaturated vapor or condensed liquid. The supersaturated vapor or condensed liquid flows through the vents (32) of the division plate (3) back to the guiding layer (2) located between the bottom plate (1) and the division plate (3). The guiding layer (2) is disposed in the first chamber (7), with the top thereof contacting the division plate (3) and the bottom thereof contacting the bottom plate (1). As shown in FIGS. 4A, 4B and 4C, the top of guiding layer (2) firmly contacts the division plate (3) while the bottom of the guiding layer (2) tightly adheres to the inner surface of bottom plate (1). Furthermore, the guiding layer (2) can be made of fine nets or porous material, or be processed by depositing metal powder thereon by thermal spray or be processed by plating, to enhance capillary flow of coolant from the cooled side (12) of the bottom plate (1) to the heated side (11) of the bottom plate (1) Meanwhile, condensed coolant droplets formed near the vents (31) of the division plate (3) can flow toward to the guiding layer (2) through capillary action. The bottom plate (1) can also have rough surfaces (e.g. be grooved or corrugated, or by chemical etching, deposition of metal powder or plating) in the first chamber (7) to promote the capillary action therein. The supersaturated vapor or condensed liquid in the first chamber (7) flows from the cooled side (12) to the heated side (11) guided by the guiding layer (2) via capillary pressure. In conclusion, the second chamber (6) allows the superheated vapor to flow therethrough and the first chamber (7) allows the supersaturated (condensed) coolant to flow therethrough. The second and first chambers (6), (7) are partitioned by the division plate (3). The coolant flows in cycles to transmit heat from the heated side (11) to the cooled side (12). In order to avoid the formation of large droplets, the inner surface of top plate (4) has to be roughened in the same manner as the bottom plate (1).

The heat sink of the present invention is manufactured in accordance with the following manner: The top and bottom plates are machined to the desired configuration. Both the division plate and guiding layer are then disposed between the top and bottom plates, and the plates can be firstly joined by laser welding, electron-beam welding, resistance welding, brazing, glue or mechanical pressing. The heat sink is then filled with coolant (generally water) and finally hermetically sealed.

Requirements for constituent materials of the present invention are diverse: since the bottom plate contacts components in computers, such as CPUs, ICs, a high coefficient of heat conduction is required (e.g. pure metal or alloy containing copper, silver, aluminum etc.). The top plate and air-cooling fins are cooled via air; thus, materials of high coefficient of heat conduction are also preferred, similar to those in the bottom plate. The material of the division plate is not limited, and is selected based on weldability. It is preferred that the division plate is easily joined to the top and bottom plates. For instance, the use of the division plate in the present invention promotes the weldability of the heat sink when the top and bottom plates are made of copper. For resistance welding, the division plate provides increased resistance at the joint that facilitates the welding. For laser welding, the material of the division plate adopted by the present invention promotes the absorption of the laser beam by copper.

In the present invention, the guiding layer in the first chamber can be manufactured by etching, embossing, shaving, or other mechanical or chemical processing. Disposed powders or fine nets on the inner surfaces of the bottom plate is also feasible.

In a modified embodiment, the above-mentioned guiding layer (2) is not adopted. In such an embodiment, however, the surface of the bottom plate (1) in the first chamber (7) is necessarily rough to function the same as the guiding layer.

In another modified embodiment, the above-mentioned division plate (3) is not adopted. Then, a single space is defined between the top plate (4) and the bottom plate (1). The coolant flows in cycles in the space. The flow of coolant is supersaturated near the bottom plate (1) and is superheated near the top plate (4).

The conventional heat pipe has a limited heat transfer capacity that is determined by the external dimension of the heat pipe. The diameter of the heat pipe before being flattened is generally smaller than 8 mm. In addition, the small contact area between the heat pipe and the air-cooling fins further limits the effect of heat dissipation. Additionally, enlargement of the plates to increase heat transfer capacity is easy enough that the present invention has an impressive heat transfer capacity.

While the invention has been described by way of example and in terms of the preferred embodiment, it is to be understood that the invention is not limited to the disclosed embodiments. To the contrary, it is intended to cover various modifications and similar arrangements (as would be apparent to those skilled in the art) . Therefore, the scope of the appended claims should be accorded the broadest interpretation so as to encompass all such modifications and similar arrangements.

What is claimed is:

1. A heat sink containing coolant for dissipating heat from a heat source, including:
a first chamber containing the coolant and absorbing the heat from the heat source, vaporizing the coolant;
at least one cooling fin; and
a second chamber receiving the vaporized coolant from the first chamber, transmitting the heat from the vaporized coolant to the at least one cooling fin so that the vaporized coolant is condensed, and forcing the condensed coolant back to the first chamber via a capillary pressure.

2. A heat sink as claimed in claim 1, wherein the first chamber has rough inner surfaces.

3. A heat sink as claimed in claim 2, wherein the inner surfaces are grooved.

4. A heat sink as claimed in claim 2, wherein the inner surfaces are corrugated.

5. A heat sink as claimed in claim 2, wherein the inner surfaces are processed by chemical etching.

6. A heat sink as claimed in claim 2, wherein the inner surfaces are processed by depositing metal powder thereon.

7. A heat sink as claimed in claim 2, wherein the inner surfaces are processed by plating.

8. A heat sink as claimed in claim 1, wherein the second chamber has rough inner surfaces.

9. A heat sink as claimed in claim 8, wherein the inner surfaces are grooved.

10. A heat sink as claimed in claim 8, wherein the inner surfaces are corrugated.

11. A heat sink as claimed in claim 8, wherein the inner surfaces are processed by chemical etching.

12. A heat sink as claimed in claim 8, wherein the inner surfaces are processed by depositing metal powder thereon.

13. A heat sink as claimed in claim 8, wherein the inner surfaces are processed by plating.

14. A heat sink as claimed in claim 1, further including a guiding layer disposed in the first chamber to enhance capillary flow of the coolant in the first chamber.

15. A heat sink as claimed in claim 14, wherein the first chamber has inner surfaces, and the guiding layer tightly adheres to the inner surfaces of the first chamber.

16. A heat sink as claimed in claim 14, wherein the guiding layer is made of fine nets.

17. A heat sink as claimed in claim 14, wherein the guiding layer is made of porous material.

18. A heat sink as claimed in claim 14, wherein the guiding layer is processed by depositing metal powder thereon.

19. A heat sink as claimed in claim 14, wherein the guiding layer is processed by plating.

20. A heat sink having coolant inside for dissipating heat from a heat source, including:
a first plate contacting the heat source;
a second plate connected to the first plate to create a space therebetween;
at least one cooling fin connected to the second plate, wherein the coolant flows in the space to transmit the heat from the heat source to the at least one fin.

21. A heat sink as claimed in claim 20, further including a guiding layer disposed in the space to enhance capillary flow of the coolant in the space, wherein the guiding layer tightly adheres to the first plate.

22. A heat sink as claimed in claim 21, further including a division plate disposed in the space to partition the space into a first subspace and a second subspace, wherein the division plate defines a plurality of holes, allowing the coolant to flow between the first subspace and the second subspace.

23. A heat sink as claimed in claim 22, wherein the division plate has a plurality of protrusions in contact with the second plate.

24. A heat sink as claimed in claim 22, further including a guiding layer disposed in the first subspace, wherein the guiding layer has a top and a bottom, the top of the guiding layer firmly contacts the division plate, while the bottom of the guiding layer tightly adheres to the first plate.

25. A heat sink as claimed in claim 22, wherein the first plate, the division plate and the second plate are joined, with the division plate disposed between the first and second plates.

26. A heat sink as claimed in claim 25, wherein the first plate, the division plate and the second plate are joined by laser welding.

27. A heat sink as claimed in claim 25, wherein the first plate, the division plate and the second plate are joined by electron-beam welding.

28. A heat sink as claimed in claim 25, wherein the first plate, the division plate and the second plate are joined by resistance welding.

29. A heat sink as claimed in claim 25, wherein the first plate, the division plate and the second plate are joined by brazing.

30. A heat sink as claimed in claim 25, wherein the first plate, the division plate and the second plate are joined by glue.

31. A heat sink as claimed in claim 25, wherein the first plate, the division plate and the second plate are joined by mechanical pressing.
